(19) United States
(12) Patent Application Publication
(10) Pub. No.: US 2012/0139026 A1
(43) Pub. Date: Jun. 7, 2012

(54) SEMICONDUCTOR MEMORY DEVICE

(75) Inventor: Kiyohito NISHIHARA, Kanagawa-ken (JP)

(73) Assignee: KABUSHIKI KAISHA TOSHIBA, Tokyo (JP)

(21) Appl. No.: 13/233,703

(22) Filed: Sep. 15, 2011

(30) Foreign Application Priority Data
Dec. 3, 2010 (JP) 2010-270004

(51) Int. Cl. H01L 29/788

(52) U.S. Cl. 257/319; 257/E29.3

(57) ABSTRACT

According to one embodiment, a semiconductor memory device includes a plurality of channel regions, a first insulating film, a plurality of floating gates, a second insulating film, and a control gate. The plurality of channel regions extends in a first direction and has the same conductivity type. The first insulating film is provided on each of the channel regions. The plurality of floating gates is provided on the first insulating film and is divided into the first direction and a second direction crossing the first direction. The second insulating film is provided on each of the floating gates. The control gate is provided on the second insulating film and extends in the second direction. An inversion layer is formed on a surface of the channel region under a part between the floating gates adjacent in the first direction by a fringe electric field of the floating gate.

### CROSS-REFERENCE TO RELATED APPLICATION

This application is based upon and claims the benefit of priority from Japanese Patent Application No.2010-270004, filed on Dec. 3, 2010; the entire contents of which are incorporated herein by reference.

### FIELD

Embodiments described herein relate generally to a semiconductor memory device.

### BACKGROUND

In a non-volatile semiconductor memory device in which, a source region and a drain region, each having a conductivity type inverse to a conductivity type of a surface of a semiconductor substrate, are formed on the surface of the semiconductor substrate, if miniaturization develops, a threshold value can vary sensitively to variation in an impurity amount. Also, in a method of forming the source region and the drain region by implanting impurities into a gap between the control gates in an ion implanting method after a control gate has been processed, if the miniaturization develops, impurities are implanted into the narrow gap between the control gates. This incurs deterioration of controllability of an impurity profile in the source region and the drain region, whereby variation of the threshold value can be caused.

### BRIEF DESCRIPTION OF THE DRAWINGS

FIG. 1 is a schematic plan view exemplifying a plan layout of major elements in a semiconductor memory device of a embodiment;

FIG. 2 is a schematic cross-sectional view corresponding to an A-A′ section in FIG. 1;

FIG. 3 is a schematic cross-sectional view corresponding to a B-B′ section in FIG. 1;

FIGS. 4A and 4B are enlarged views of main section in FIG. 2;

FIGS. 5A and 5B are schematic cross-sectional views illustrating another specific example corresponding to a cross-sectional structure in FIG. 4B;

FIGS. 6A and 6B are schematic cross-sectional views illustrating still another specific example corresponding to a cross-sectional structure in FIG. 4B;

FIGS. 7A and 7B are schematic cross-sectional views illustrating another specific example corresponding to a cross-sectional structure in FIG. 4A;

FIG. 8 is a schematic cross-sectional view illustrating another specific example corresponding to a cross-sectional structure in FIG. 3; and

FIG. 9 is a schematic cross-sectional view illustrating another specific example corresponding to a cross-sectional view in FIG. 2.

### DETAILED DESCRIPTION

According to one embodiment, a semiconductor memory device includes a plurality of channel regions, a first insulating film, a plurality of floating gates, a second insulating film, and a control gate. The plurality of channel regions extends in a first direction and has the same conductivity type. The first insulating film is provided on each of the channel regions. The plurality of floating gates is provided on the first insulating film and is divided into the first direction and a second direction crossing the first direction. The second insulating film is provided on each of the floating gates. The control gate is provided on the second insulating film and extends in the second direction. An inversion layer is formed on a surface of the channel region under a part between the floating gates adjacent in the first direction by a fringe electric field of the floating gate.

Embodiments will be described below by referring to the attached drawings. In each figure, the same reference numerals are given to the same components. Also, in the following embodiments, silicon is exemplified as a semiconductor, but other semiconductors may be used.

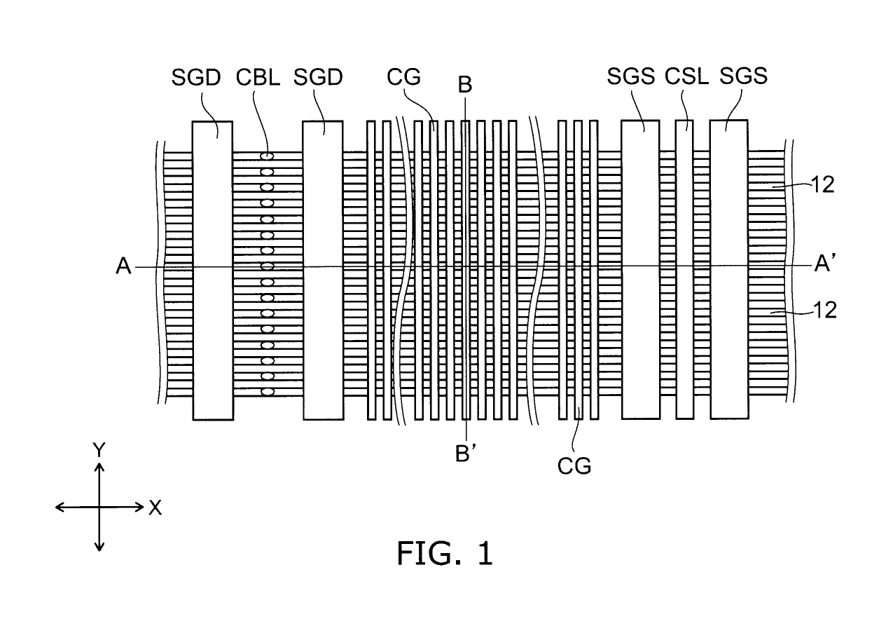

FIG. 1 is a schematic plan view exemplifying a plan layout of major elements in a semiconductor memory device of the embodiment.

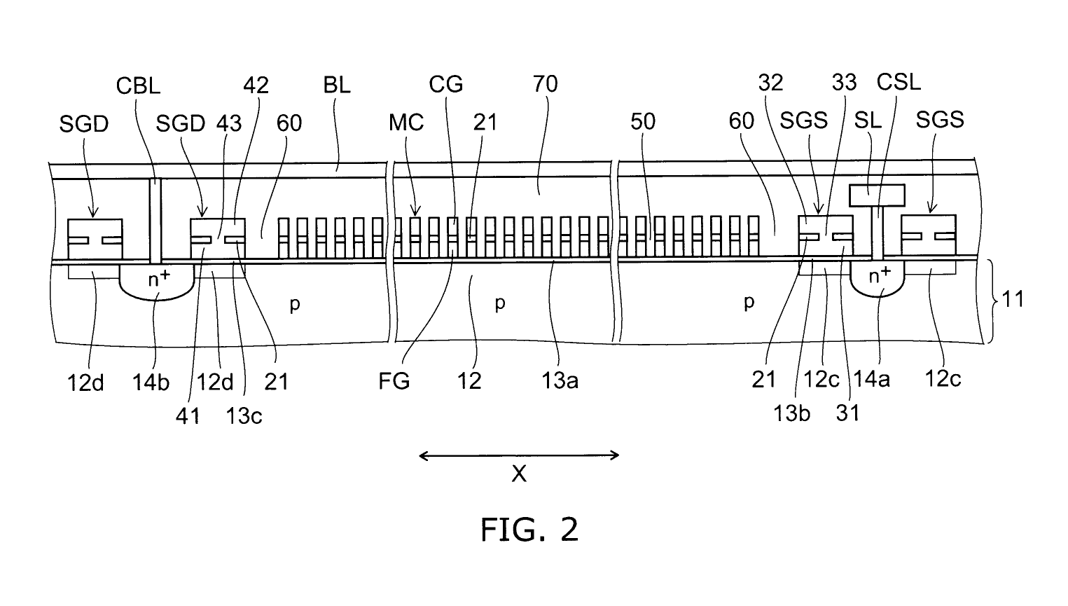

FIG. 2 is a schematic cross-sectional view corresponding to an A-A′ section in FIG. 1.

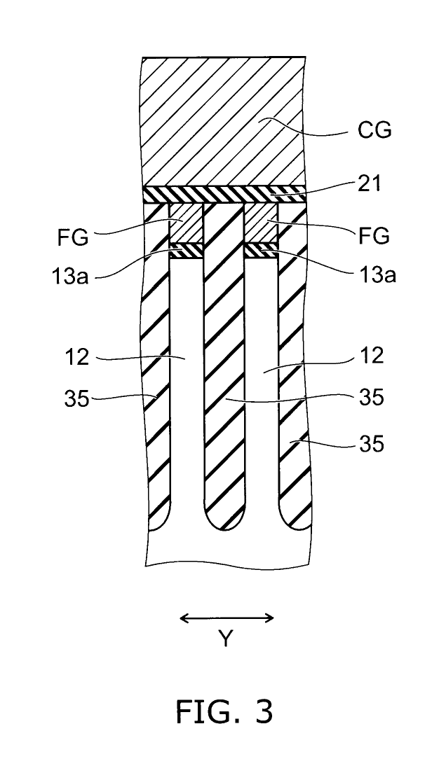

FIG. 3 is a schematic cross-sectional view corresponding to a B-B′ section in FIG. 1.

FIG. 2 illustrates a section in the vicinity of the surface of a semiconductor substrate 11. On the surface of the semiconductor substrate 11 or on the surface of a p-type well layer formed on the surface of the semiconductor substrate 11, a p-type channel region 12 is formed. The channel region 12 extends in a first direction X. Also, as illustrated in FIG. 1, a plurality of the channel regions 12 are formed by being aligned in a second direction Y, which crosses (at a right angle, for example) the first direction X. In FIG. 3, only two channel regions 12 are illustrated, but a plurality of the channel regions 12 are aligned in the second direction Y.

As illustrated in FIG. 3, the channel regions 12 adjacent in the second direction Y are separated by a Shallow Trench Isolation (STI) structure, for example. That is, a trench is formed between the channel regions 12 adjacent in the second direction Y, and in the trench, an insulator 35 made of silicon oxide or the like is buried, for example.

On the channel region 12, a tunnel insulating film 13a is provided as a first insulating film. The tunnel insulating film 13a is a silicon oxide film, for example. The tunnel insulating film 13a extends in the first direction X as illustrated in FIG. 2. Also, as illustrated in FIG. 3, the tunnel insulating film 13a is divided into plural parts in the second direction Y.

On the tunnel insulating film 13a, a plurality of floating gates FG are provided. The floating gate FG is a polycrystalline silicon film to which phosphorous, for example, is added as an impurity to give conductivity. Alternatively, silicon to which carbon is further added in addition to phosphorous, tungsten, titanium nitride, tantalum nitride or the like may be used as a floating gate FG.

As illustrated in FIG. 2, the plurality of floating gates FG are divided in the first direction X. Also, as illustrated in FIG. 3, the plurality of floating gates FG are divided also in the second direction Y.

On the floating gate FG, an inter-layer insulating film 21 is provided as a second insulating film. The inter-layer insulating film 21 is made of a material having relative dielectric constant higher than that of the tunnel insulating film 13a. As the inter-layer insulating film 21, at least any one of silicon oxide, silicon nitride, lanthanum aluminate, lanthanum silicate, lanthanum aluminum silicate, aluminum oxide, hafnium aluminate, hafnium silicate, zinc oxide, tantalum oxide, strontium oxide, silicon nitride, magnesium oxide, yttrium oxide, hafnium oxide, zirconium oxide, and bismuth oxide can be used. Alternatively, a mixture of a plurality of them or a composite film or a composite film of those other than silicon oxide among them and silicon oxide can be also used as the inter-layer insulating film 21.

The inter-layer insulating film 21 is divided into plural parts in the first direction X as illustrated in FIG. 2. Also, the inter-layer insulating film 21 extends in the second direction Y as illustrated in FIG. 3.

On the inter-layer insulating film 21, a control gate CG is provided. For the control gate CG, the same material as that of the floating gate FG can be used. As illustrated in FIG. 2, the control gate CG is divided into plural parts in the first direction X. Also, as illustrated in FIGS. 1 and 3, the control gate CG extends in the second direction Y.

As illustrated in FIG. 3, an insulator 35 is provided between the floating gates FG adjacent in the second direction Y and between the tunnel insulating films 13a. Also, as illustrated in FIG. 2, a dielectric body 50 is provided also between the floating gates FG adjacent in the first direction X and between the inter-layer insulating films 21.

The floating gate FG is located at an intersection part between the control gate CG and the active region 12. That is, on the semiconductor substrate 11, a plurality of memory cells MC (hereinafter referred also simply as a cell) are laid out in the matrix. One cell MC includes one floating gate FG surrounded by the insulator.

The floating gate FG is covered by the insulator and not connected to anywhere electrically. Thus, even if power is turned off, electrons accumulated in the floating gate FG do not leak out of the floating gate FG or new electrons do not enter therein. That is, the semiconductor memory device of the embodiment is a non-volatile semiconductor memory device that can maintain data without supplying power.

The plurality of cells MC are connected in series in the first direction X and form a cell row. Moreover, at both ends in the first direction X of the cell row, selection gate transistors are connected. The cell row and the selection gate transistors are connected in series between a source line SL and a bit line BL illustrated in FIG. 2 and form a memory string. In FIG. 1, the source line SL and the bit line BL are not shown.

As illustrated in FIG. 2, the source line SL is connected to the channel region 12 through a source-line contact CSL and an n⁺-type semiconductor region 14a. The n⁺-type semiconductor region 14a is formed on the surface of the channel region 12 at one of ends of the cell row. The source-line contact CSL is provided on the n⁺-type semiconductor region 14a and is electrically connected to the n⁺-type semiconductor region 14a.

A source-side selection transistor is provided between the cell row and the n⁺-type semiconductor region 14a. The source-side selection transistor has a source-side selection gate SGS. The source-side selection gate SGS is provided on the channel region 12 outside in the first direction X of the cell row through a gate insulating film 13b.

The source-side selection gate SGS is separated from the floating gate FG and the control gate CG on the utmost ends of the cell row. A dielectric body 60 is provided between the cell row and the source-side selection gate SGS. The width in the first direction X of the dielectric body 60 is larger than the width in the first direction X of the dielectric body 50 between the cells MC. Alternatively, the width in the first direction X of the dielectric body 60 between the cell row and the source-side selection gate SGS may be the same as the width in the first direction X of the dielectric body 50 between the cells MC.

The source-side selection gate SGS has a first part 31 and a second part 32. The first part 31 is formed in the same process and of the same material as those of the floating gate FG of the cell MC and is provided on the gate insulating film 13b. The second part 32 is formed in the same process and of the same material as those of the control gate CG of the cell MC. Between the first part 31 and the second part 32, an inter-layer insulating film 21 formed in the same process and of the same material as those of the inter-layer insulating film 21 of the cell MC is provided. However, the first part 31 and the second part 32 are connected to each other through a contact part 33 penetrating a part of the inter-layer insulating film 21.

A pair of the source-side selection gates SGS are provided by sandwiching the n⁺-type semiconductor region 14a in the first direction X. Each of the source-side selection gates SGS enables connection between different cell rows and the source line SL, respectively. That is, the source line SL is shared among the plurality of memory strings.

The bit line BL is connected to the channel region 12 through a bit-line contact CBL and an n⁺-type semiconductor region 14b. The n⁺-type semiconductor region 14b is formed on the surface of the channel region 12 at the other end of the cell row. The bit-line contact CBL is provided on the n⁺-type semiconductor region 14b and is electrically connected to the n⁺-type semiconductor region 14b.

Between the cell row and the n⁺-type semiconductor region 14b, a drain-side selection transistor is provided. The drain-side selection transistor has a drain-side selection gate SGD. The drain-side selection gate SGD is provided on the channel region 12 outside in the first direction X of the cell row through a gate insulating film 13c.

The drain-side selection gate SGD is separated with respect to the floating gate FG at the utmost end of the cell row and the control gate CG. The dielectric body 60 is provided between the cell row and the drain-side selection gate SGD. The width in the first direction X of the dielectric body 60 is larger than the width in the first direction X of the dielectric body 50 between the cells MC. Alternatively, the width in the first direction X of the dielectric body 60 between the cell row and the drain-side selection gate SGD may be the same as the width in the first direction X of the dielectric body 50 between the cells MC.

The drain-side selection gate SGD has a first part 41 and a second part 42. The first part 41 is formed in the same process and of the same material as those of the floating gate FG of the cell MC and is provided on the gate insulating film 13c. The second part 42 is formed in the same process and of the same material as those of the control gate CG of the cell MC. Between the first part 41 and the second part 42, the inter-layer insulating film 21 formed in the same process and of the same material as those of the inter-layer insulating film 21 of the cell MC is provided. However, the first part 41 and the second part 42 are connected to each other through a contact part 43 penetrating a part of the inter-layer insulating film 21.

A pair of the drain-side selection gates SGD are provided by sandwiching the n⁺-type semiconductor region 14b in the first direction X. Each of the drain-side selection gates SGD enables connection between different cell rows and the bit line BL, respectively. That is, the bit line BL is shared among the plurality of memory strings.

As illustrated in FIG. 1, the source-side selection gate SGS, the drain-side selection gate SGD, and the source-line contact CSL extend in the second direction Y. The source line SL is laid out across the plurality of channel regions 12 aligned in the second direction Y, and the plurality of channel regions 12 can be connected to the common source line SL. The bit line BL extends, as illustrated in FIG. 2, in the first direction X. The plurality of bit lines BL are provided in a number corresponding to the number of the plurality of channel regions 12 aligned in the second direction Y.

On the control gate CG, on the source-side selection gate SGS, and on the drain-side selection gate SGD, an inter-layer insulating film 70 is provided, and on the inter-layer insulating film 70, the bit line BL is provided. The source line SL is covered by the inter-layer insulating film 70 and is insulated from the bit lint BL and the source-side selection gate SGS.

Under the cell row, under the source-side selection gate SGS, under a part between the cell row and the source-side selection gate SGS, under the drain-side selection gate SGD, and under a part between the cell row and the drain-side selection gate SGD, the p-type channel regions 12 are successively formed. That is, in one memory string having the n⁺-type semiconductor regions 14a and 14b on the both ends, the channel regions 12 between the n⁺-type semiconductor regions 14a and 14b have the same conductivity type (p-type). The channel region 12 functions as a path through which a current flows between the source line SL and the bit line BL.

When a desired potential (positive potential) is given to the control gate CG, the potential is given also to the floating gate FG capacity-coupled with the control gate CG through the inter-layer insulating film 21. By the potential of the floating gate FG, an inversion layer (n-type channel) is formed in a region located under the floating gate FG through the tunnel insulating film 13a in the channel region 12.

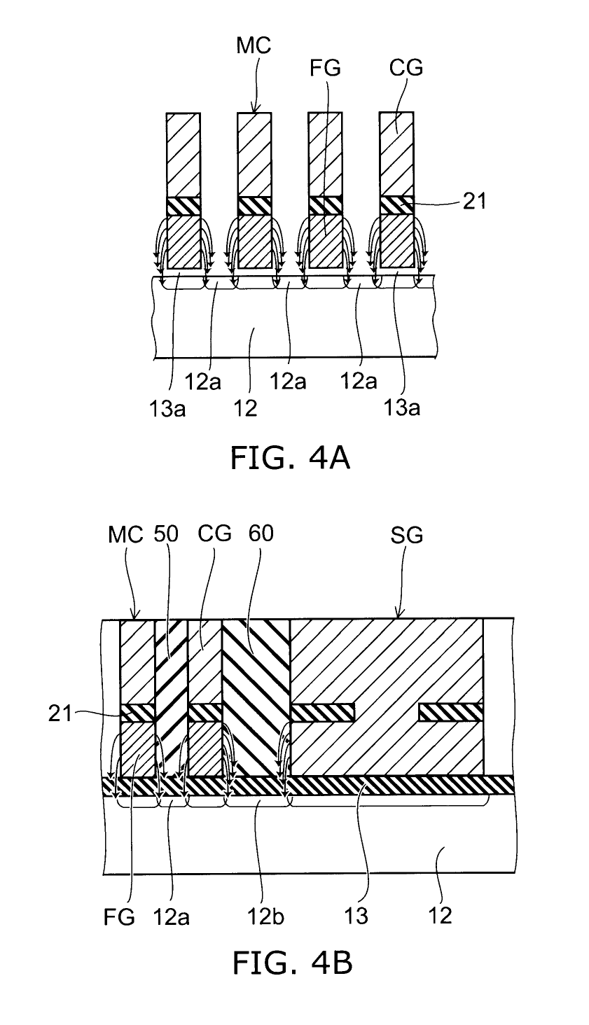

Also, in the embodiment, as illustrated in FIG. 4A, an inversion layer (n-type channel) is formed on the surface of the channel region 12a under a part between the floating gates FG adjacent in the first direction X by a fringe electric field of the floating gate FG. Lines of electric force by the fringe electric field of the floating gate FG are schematically indicated by arrows in FIG. 4A.

As a result, the inversion layer generated immediately under the floating gate FG and the inversion layer generated in the region 12a under the part between the floating gates FG adjacent in the first direction X can be connected to each other in the first direction X. That is, in the embodiment, without forming an impurity diffusion region (a source region and a drain region) having a conductivity type (n-type) inverse to that of the channel region 12 in the region 12a under the part between the floating gates FG adjacent in the first direction X in which the channel region 12 extends, a normal operation can be performed by obtaining a sufficient ON current.

In the embodiment, since the source region and the drain region are not formed in the channel region 12a under the part between the floating gates FG, variation in the threshold value caused by the variation in the impurity amount in those regions can be prevented.

Also, the source region and the drain region are formed by the ion implantation method after the control gate CG has been processed in general. Particularly if miniaturization of the cell MC develops, the impurity is implanted into a narrow gap between the cells MC in the ion implantation, which makes control of impurity profile difficult, combined with variation in line and space. However, in the embodiment, since ion does not have to be implanted into a space between the cells MC, the variation in the threshold value cause by the variation in the impurity profile can be prevented.

FIG. 4B illustrates a section of the part between the cell row and the source-side selection gate SGS or the part between the cell row and the drain-side selection gate SGD. In FIG. 4B, the source-side selection gate SGS and the drain-side selection gate SGD are not discriminated from each other but they are indicated simply as a selection gate SG. That is, the selection gate SG corresponds to the source-side selection gate SGS or the drain-side selection gate SGD.

In the channel region 12, an n-type impurity diffusion region is not formed in a region 12b under the part between the cell row and the selection gate SG. That is, the region 12b under the part between the cell row and the selection gate SG is also of a p-type.

Then, by the fringe electric field of the floating gate FG at the utmost end on the selection gate SG side in the cell row and the fringe electric field of the selection gate SG, an inversion layer (n-type channel) is formed also in the region 12b under a part between the cell row and the selection gate SG. The lines of electric force by those fringe electric fields are schematically illustrated by arrows in FIG. 4B.

As a result, an inversion layer generated under the floating gate FG, an inversion layer generated in the region 12a under the part between the adjacent floating gates FG, an inversion layer generated under the selection gate SG, and an inversion layer generated in the region 12b under the part between the cell row and the selection gate SG can be connected.

That is, without forming an impurity diffusion region having a conductivity type (n-type) inverse to that of the channel region 12 in the region 12b under the part between the cell row and the selection gate SG, the channel of the cell row can be electrically connected to the source line SL and the bit line BL.

In the embodiment, as described above, ion implantation for forming an impurity diffusion region in the channel region 12 of the cell row is no longer necessary. Moreover, ion implantation is no longer necessary for the region 12b under the part between the cell row and the selection gate SG, either. As a result, the number of processes can be reduced, and a cost can be cut.

In the process, the distance between the cell MC and the selection gate SG tends to become larger than the pitch in the first direction X between the cells MC. Therefore, in the region 12b in which the width in the first direction X is larger than the distance between the cells MC, electron density induced by the fringe electric field can become insufficient, which can cause a drop in the ON current.

Therefore, between the floating gate FG at the utmost end of the cell row and the selection gate SG, the dielectric body 60 having relative dielectric constant higher than that of the dielectric body 50 provided between the cells MC is notably provided. As the dielectric bodies 50 and 60, not limited to one type of film but a composite film made of a plurality of types of film may be used. In this case, average relative dielectric constant of the dielectric body 60 is set higher than the average relative dielectric constant of the dielectric body 50.

By using the dielectric body 60 having high relative dielectric constant, the capacity between the floating gate FG at the end of the cell row and the region 12b, and the capacity between the selection gate SG and the region 12b can be increased. As a result, electrons with sufficient density can be induced by the fringe electric field also in the region 12b larger than the part between the cells MC.

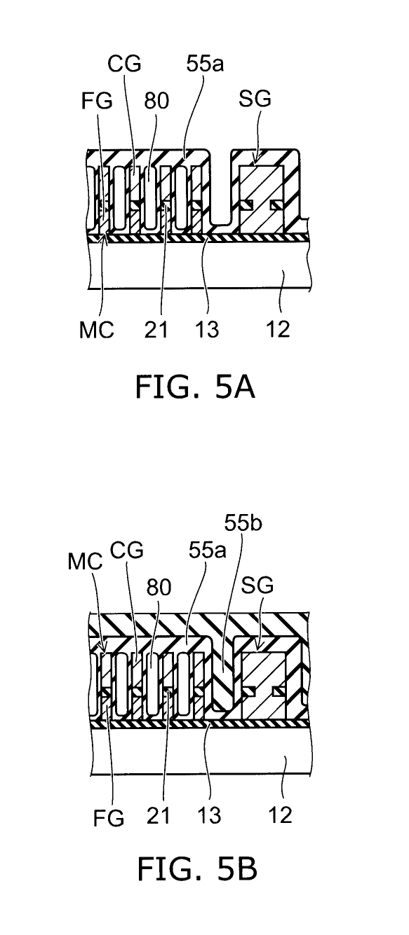

For example, as illustrated in FIG. 5B, a gap 80 is formed between the cells MC. Inert gas such as nitrogen and the like is contained in the gap 80. Dielectric bodies 55a and 55b between the cell MC and the selection gate SG contain silicon oxide having relative dielectric constant higher than that of a gas contained in the gap 80.

After the floating gate FG, the control gate CG, and the selection gate SG have been processed, as illustrated in FIG. 5A, a silicon oxide film 55a is formed on an exposed part of the floating gate FG, the control gate CG, and the selection gate SG by a chemical vapor deposition (CVD) method, for example. By controlling the film forming condition (time, gas type, gas flow, in-chamber pressure and the like) at this time, the gap 80 can be generated between the cells MC.

After that, by the CVD method, again, for example, a silicon oxide film 55b is deposited. As a result, as illustrated in FIG. 5B, a gap between the cell MC and the selection gate SG is filled with the silicon oxide films 55a and 55b.

Between the adjacent floating gates FG in the cell row, the gap 80 having low relative dielectric constant than that of the silicon oxide film is formed. Thus, interference between the cells such as threshold value variation caused by capacity-coupling between the adjacent floating gates FG can be suppressed.

It is only necessary that the average dielectric constant of the dielectric body between the cell MC and the selection gate SG is relatively higher than the average dielectric constant of the dielectric body between the cells MC.

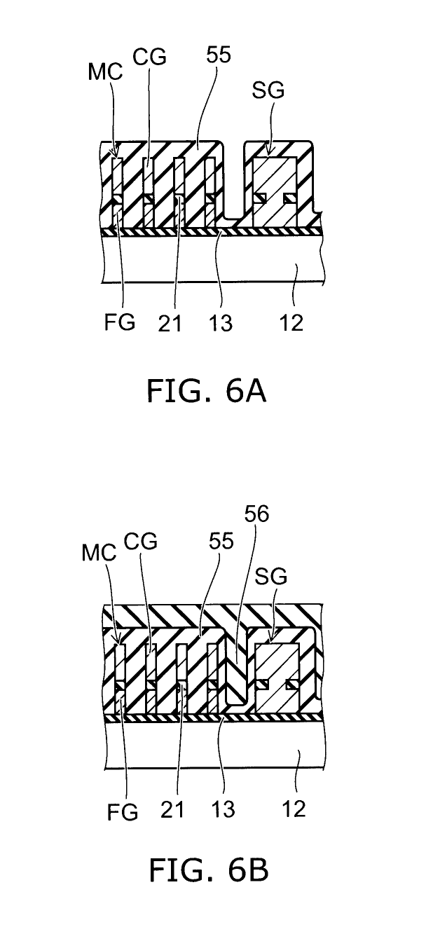

For example, as illustrated in FIG. 6B, the structure may be such that the dielectric body 55 between the cells MC contains silicon oxide and the dielectric body 56 between the cell MC and the selection gate SG contains silicon nitride having relative dielectric constant higher than that of silicon oxide.

After the floating gate FG, the control gate CG, and the selection gate SG have been processed, as illustrated in FIG. 6A, the silicon oxide film 55 is formed on an exposed part of the floating gate FG, the control gate CG, and the selection gate SG by the CVD method, for example. At this time, a gap between the cells MC is filled with the silicon oxide film 55. The gap between the cell MC and the selection gate SG larger than the gap between the cells MC is not filled with the silicon oxide film 55.

After that, by the CVD method, for example, a silicon nitride film 56 is deposited. As a result, as illustrated in FIG. 6B, inside the silicon oxide film 55 between the cell MC and the selection gate SG is filled with the silicon nitride film 56.

Referring back to FIG. 1, the tunnel insulating film 13a between the floating gate FG and the channel region 12, the gate insulating film 13b between the source-side selection gate SGS and the channel region 12, and the gate insulating film 13c between the drain-side selection gate SGD and the channel region 12 are formed in the same process and of the same material and have the same thickness.

Also, the control gate CG and the floating gate FG are capacity-coupled by the inter-layer insulating film 21. On the other hand, in the source-side selection gate SGS, the first part 31 corresponding to the floating gate FG of the cell MC and the second part 32 corresponding to the control gate CG are directly connected to each other. Similarly, in the drain-side selection gate SGD, too, the first part 41 and the second part 42 are directly connected to each other.

Therefore, in order to adjust the threshold value of the cell MC and the threshold value of the selection transistor as appropriate, the p-type impurity concentration of the channel region 12 under the floating gate FG and the p-type impurity concentration of the channel region 12 under the selection gate are different from each other.

That is, the p-type impurity concentration of a channel region (indicated by a broken line in FIG. 2) 12c under the source-side selection gate SGS is different from the p-type impurity concentration of the channel region 12 of the cell MC. Similarly, the p-type impurity concentration of a channel region (indicated by a broken line in FIG. 2) 12d under the drain-side selection gate SGD is different from the p-type impurity concentration of the channel region 12 of the cell MC.

If the p-type impurity concentrations of the channel regions 12c and 12d under the selection gate are relatively high, the channel regions 12c and 12d having the high impurity concentrations are limited to immediately under the selection gates and notably do not extend to the channel region between the cell row and the selection gate. Since the p-type region with high impurity concentration is not present in the channel region between the cell row and the selection gate, electron induction with sufficient density is made possible by the above-described fringe electric field.

The cell MC in the embodiment has a stack gate (double gate) structure in which the control gate CG and the floating gate FG are stacked through the inter-layer insulating film 21. In the cell having such structure in which the two gates are stacked, it is more effective to use the fringe electric field of the floating gate FG closer to the channel region 12 than the control gate CG.

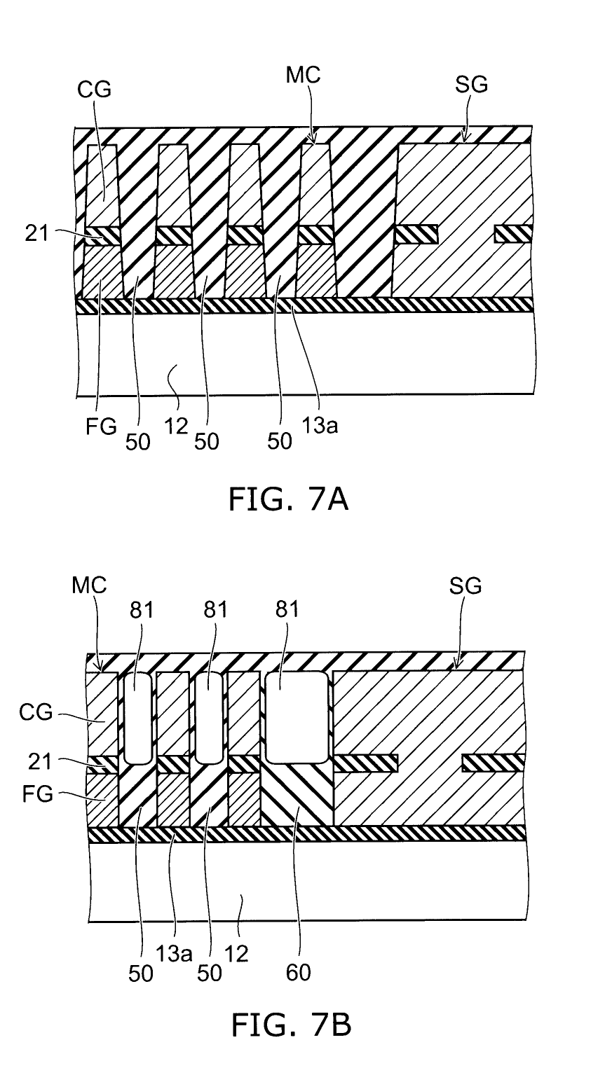

By referring to FIGS. 7A and 7B, an example of the structure which further improves a working effect of the fringe electric field of the floating gate FG will be described below.

For example, through condition control of anisotropic etching (Reactive Ion Etching (RIE), for example) when a stack gate is processed or through appropriate design of an aspect ratio (ratio of depth to width) of the trench between the stack gates, as illustrated in FIG. 7A, the trench whose width gradually decreases from the upper part to the lower part (bottom part) is formed between the stack gates adjacent in the first direction X.

As a result, the width of the stack gate including the floating gate FG and the control gate CG adjacent to the trench gradually increases from the upper part to the lower part (bottom part) to the contrary to the trench. That is, the section of the stack gate becomes trapezoidal.

Therefore, the maximum width in the first direction X of the floating gate FG is larger than the maximum width in the first direction X of the control gate CG. The width in the first direction X of the lower part on the channel region 21 side of the floating gate FG is larger than the width in the first direction X of the upper part on the control gate CG side of the floating gate FG. In the stack gate, since the gate width of a part closer to the channel region 12 is larger, the influence of the fringe electric field of the floating gate FG to the channel region 12 under the part between the cells MC can be improved.

Also, as illustrated in FIG. 7B, also by setting the average relative dielectric constant of the dielectric body between the floating gates FG adjacent in the first direction X higher than the average relative dielectric constant of the dielectric body between the control gates CG adjacent in the first direction X, the influence of the fringe electric field of the floating gate FG to the channel region 12 under the part between the cells MC can be improved.

In FIG. 7B, the silicon oxide film 50 is provided between the floating gates FG, and the gap 81 containing the inert gas having relative dielectric constant lower than that of the silicon oxide film such as nitrogen, for example, is provided between the control gates CG, for example. As a result, the coupling capacity between the floating gate FG and the channel region 12 under the part between the cells MC is increased so that the fringe electric field of the floating gate FG can effectively act on the channel region 12 under the part between the cells MC.

Moreover, the gap 81 may be formed between the part above the inter-layer insulating film 21 in the selection gate SG and the cell row. In this case, too, the fringe electric field of the part closer to the channel region 12 and under the inter-layer insulating film 21 in the selection gate SG can be effectively used.

Depletion of the floating gate FG using a silicon film, for example, added carbon may be suppressed. As a result, an increase in the effective insulating film thickness between the floating gate FG and the channel region 12 can be suppressed. As a result, the lower end of the floating gate FG becomes substantially close to the channel region 12, and the fringe electric field of the floating gate FG can be made to effectively act on the channel region 12 under the part between the cells MC.

In order to increase the influence of the fringe electric field of the floating gate FG to the channel region 12, it is effective to suppress the depletion on the lower part on the tunnel insulating film 13 side in the floating gate FG. Therefore, carbon is notably added to the lower part on the tunnel insulating film 13 side in the floating gate FG. For example, as the structure of the floating gate FG using silicon, a stack structure of a first layer containing carbon provided on a part in contact with the tunnel insulating film 13 and a second layer not containing carbon provided on the first layer can be employed.

Alternatively, if a metal film is used for the floating gate FG, too, the depletion of the floating gate FG can be suppressed, and the fringe electric field of the floating gate FG can be made to effectively act on the channel region 12 under the part between the cells MC.

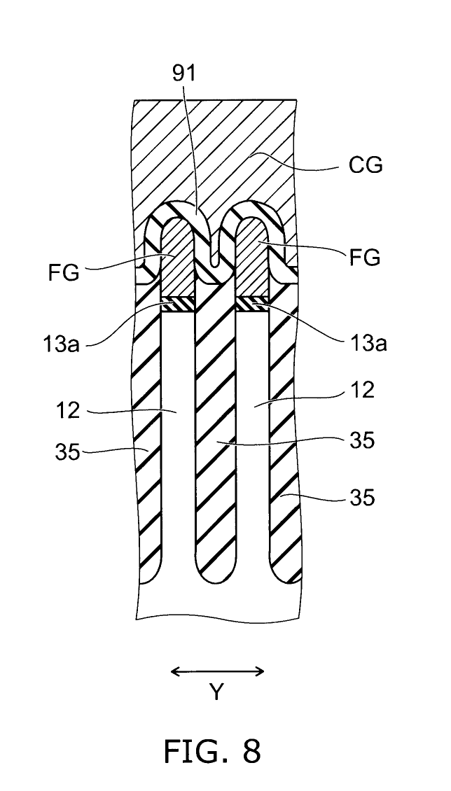

FIG. 8 illustrates another specific example of the structure of the cell MC. FIG. 8 corresponds to a sectional structural part in FIG. 3, that is, corresponds to the B-B′ section in FIG. 1.

In this structure, too, an inter-layer insulating film 91 provided between the floating gate FG and the control gate CG is divided into plural parts in the first direction X and continues in the second direction Y. Moreover, the inter-layer insulating film 91 is provided also on a part of the side face of the floating gate FG. The side face faces another floating gate FG adjacent in the second direction Y.

By providing the inter-layer insulating film 91 not only on the top face of the floating gate FG but also on the side face of the floating gate FG, the capacity between the floating gate FG and the control gate CG through the inter-layer insulating film 91 can be increased. As a result, a writing voltage can be lowered.

Also, by increasing the coupling capacity between the floating gate FG and the control gate CG, without increasing the potential to be given to the control gate CG so much, electrons with sufficient density can be induced in the channel region 12 under the part between the cells MC by the fringe electric field of the floating gate FG.

Also, in the embodiment, as compared with the structure illustrated in FIG. 3, the size in the height direction of the floating gate FG is increased. The influence of the fringe electric field of the floating gate FG to the channel region 12 is increased by that portion.

Also, between the floating gates FG adjacent in the second direction Y, a part of the control gate CG is provided with the inter-layer insulating film 91 interposed. By a shield effect of the control gate CG, inter-cell interference caused by capacity coupling between the adjacent floating gates FG can be suppressed.

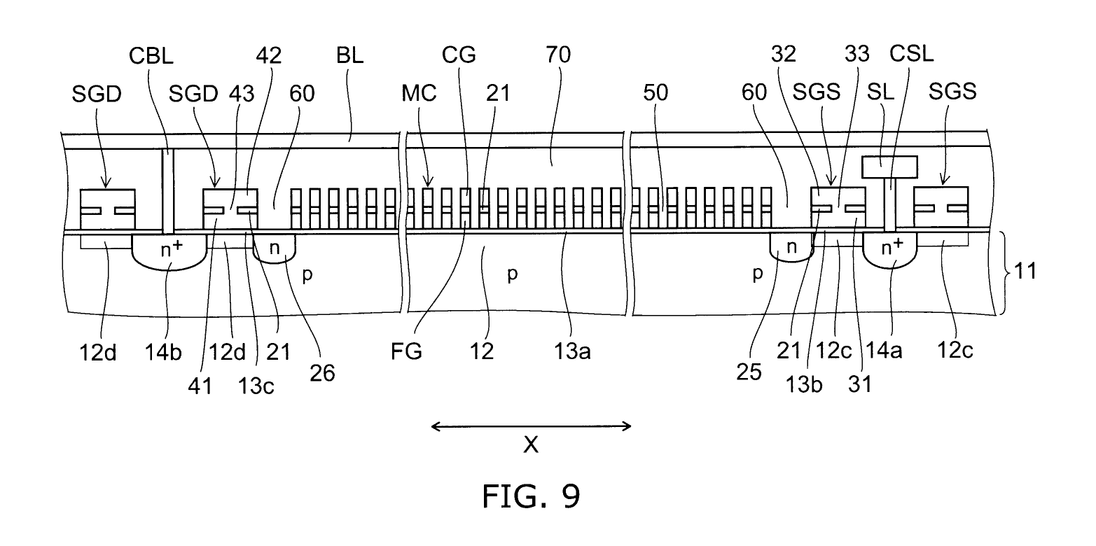

As illustrated in FIG. 9, an n-type impurity diffusion region 25 may be formed in a region under the part between the cell row and the source-side selection gate SGS. Similarly, an n-type impurity diffusion region 26 may be formed in a region under the part between the cell row and the drain-side selection gate SGD.

In the above-described embodiment, the region described as the p-type may be the n-type and the region described as the n-type may be the p-type. That is, such a structure may be employed that an n-type channel region extends in the first direction X.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a plurality of channel regions extending in a first direction and having the same conductivity type;
a first insulating film provided on each of the channel regions;
a plurality of floating gates provided on the first insulating film and divided into the first direction and a second direction crossing the first direction;
a second insulating film provided on each of the floating gates; and
a control gate provided on the second insulating film and extending in the second direction,
an inversion layer being formed on a surface of the channel region under a part between the floating gates adjacent in the first direction by a fringe electric field of the floating gate.

2. The device according to claim 1, wherein
a maximum width in the first direction of the floating gate is larger than a maximum width in the first direction of the control gate.

3. The device according to claim 2, wherein
a width in the first direction of a lower part on the channel region side of the floating gate is larger than a width in the first direction of an upper part on the control gate side of the floating gate.

4. The device according to claim 1, further comprising:
a first dielectric body provided between the floating gates adjacent in the first direction; and
a second dielectric body provided between the control gates adjacent in the first direction,
an average relative dielectric constant of the first dielectric body being higher than an average relative dielectric constant of the second dielectric body.

5. The device according to claim 1, further comprising:
a third insulating film provided on the channel region and provided at an end of a cell row including the plurality of floating gates aligned in the first direction; and
a selection gate separated from the floating gate and the control gate, provided on the third insulating film and extending in the second direction,
the channel region of the same conductivity type continuing under the cell row, under the selection gate, and under a part between the cell row and the selection gate.

6. The device according to claim 5, wherein
an impurity concentration of the channel region under the selection gate is different from an impurity concentration of the channel region under the cell row.

7. The device according to claim 5, further comprising:
a third dielectric body provided between the floating gates adjacent in the first direction in the cell row; and
a fourth dielectric body provided between the floating gate at the end of the cell row and the selection gate,
an average relative dielectric constant of the fourth dielectric body being higher than an average relative dielectric constant of the third dielectric body.

8. The device according to claim 7, wherein
a gap is provided between the floating gates adjacent in the first direction; and
the fourth dielectric body contains silicon oxide.

9. The device according to claim 7, wherein
the third dielectric body contains silicon oxide; and
the fourth dielectric body contains silicon nitride.

10. The device according to claim 1, wherein
carbon is added at least to the first insulating film side in the floating gate.

11. The device according to claim 1, wherein
the floating gate is a metal film.

12. A semiconductor memory device comprising:
a plurality of channel regions extending in a first direction and having the same conductivity type;
a first insulating film provided on each of the channel regions;
a plurality of floating gates provided on the first insulating film and divided into the first direction and a second direction crossing the first direction;
a second insulating film provided on a top face and a side face in the second direction of each of the floating gates; and
a control gate provided on the second insulating film and between the floating gates adjacent in the second direction and extending in the second direction.

13. The device according to claim 12, wherein
an inversion layer is formed on a surface of the channel region under a part between the floating gates adjacent in the first direction by a fringe electric field of the floating gate.

14. The device according to claim 12, wherein
a maximum width in the first direction of the floating gate is larger than a maximum width in the first direction of the control gate.

15. The device according to claim 14, wherein
the width in the first direction of a lower part on the channel region side of the floating gate is larger than the width in the first direction of an upper part on the control gate side of the floating gate.

16. The device according to claim 12, further comprising:
a first dielectric body provided between the floating gates adjacent in the first direction; and
a second dielectric body provided between the control gates adjacent in the first direction,
an average relative dielectric constant of the first dielectric body being higher than an average relative dielectric constant of the second dielectric body.

17. The device according to claim 12, further comprising:
a third insulating film provided on the channel region and provided at an end of a cell row including the plurality of floating gates aligned in the first direction; and
a selection gate separated from the floating gate and the control gate, provided on the third insulating film and extending in the second direction,
the channel region of the same conductivity type continuing under the cell row, under the selection gate, and under a part between the cell row and the selection gate.

18. The device according to claim 17, wherein
an impurity concentration of the channel region under the selection gate is different from an impurity concentration of the channel region under the cell row.

19. The device according to claim 17, further comprising:
a third dielectric body provided between the floating gates adjacent in the first direction in the cell row; and
a fourth dielectric body provided between the floating gate at the end of the cell row and the selection gate,
an average relative dielectric constant of the fourth dielectric body being higher than an average relative dielectric constant of the third dielectric body.

20. The device according to claim 19, wherein
a gap is provided between the floating gates adjacent in the first direction; and
the fourth dielectric body contains silicon oxide.

21. The device according to claim 19, wherein
the third dielectric body contains silicon oxide; and
the fourth dielectric body contains silicon nitride.

22. The device according to claim 12, wherein
carbon is added at least to the first insulating film side in the floating gate.

23. The device according to claim 12, wherein
the floating gate is a metal film.
